(19) United States
(12) Patent Application Publication
(10) Pub. No.: US 2011/0127646 A1
(43) Pub. Date: Jun. 2, 2011

(54) WAFER AND METHOD FOR FORMING THE SAME

(75) Inventors: Hee Bok KANG, Cheongju (KR); Young Wug Kim, Seoul (KR); Si Choon Yeom, Chungcheongbuk-do (KR)

(73) Assignee: Hynix Semiconductor Inc., Icheon (KR)

(21) Appl. No.: 12/828,072

(22) Filed: Jun. 30, 2010

(30) Foreign Application Priority Data
Nov. 27, 2009 (KR) 10-2009-0115596

(51) Int. Cl. H01L 23/544; H01L 21/50

(52) U.S. Cl. 257/620; 438/107; 257/E23.179; 257/E21.499

(57) ABSTRACT

A wafer and a method for forming the same are disclosed. The wafer forming method can separate respective chips from others by performing a Deep Reactive Ion Etching (DRIE) process on a wafer including a plurality of chips. The wafer includes a plurality of chips configured to be arranged in row and column directions on the wafer, a scribe lane formed among the plurality of chips, configured to separate each of the plurality of chips using a Deep Reactive Ion Etching (DRIE) process, and an alignment key pattern configured to be arranged on the plurality of chips. The DRIE process is performed at a front side of the wafer on a basis of the align key pattern.

### CROSS-REFERENCE TO RELATED APPLICATION

The priority of Korean patent application No. 10-2009-0115596 filed on Nov. 27, 2009, the disclosure of which is hereby incorporated in its entirety by reference, is claimed.

### BACKGROUND OF THE INVENTION

Embodiments of the present invention relate to a wafer and a method for forming the same, and more specifically, to a technology for separating a plurality of chips from a wafer.

A radio frequency identification (RFID) tag chip has been widely used to identify objects using a radio frequency (RF) signal. In order to automatically identify an object using the RFID tag chip, an RFID tag is first attached to the object to be identified, and an RFID reader wirelessly communicates with the RFID tag of the object using a non-contact automatic identification scheme can be implemented. With the widespread use of these RFID technologies, the shortcomings of a conventional automatic identification technology, such as a barcode and an optical character recognition technology, can be greatly reduced.

In recent times, the RFID tag has been widely used in physical distribution management systems, user authentication systems, electronic money (e-money), transportation systems, and the like.

For example, the physical distribution management system generally performs a classification of goods or management of goods in stock by recording data in an Integrated Circuit (IC) instead of using a delivery note or tag. In addition, the user authentication system generally performs an Entrance and Exit Management function using an IC card including personal information or the like.

In the meantime, a non-volatile ferroelectric memory may be used as a memory in an RFID tag.

Generally, a non-volatile ferroelectric memory [e.g., a Ferroelectric Random Access Memory (FeRAM)] has a data processing speed similar to that of a Dynamic Random Access Memory (DRAM). The non-volatile ferroelectric memory also preserves data even when power is turned off. Because of these properties many developers are conducting intensive research into FeRAM as a next generation memory device.

The above-mentioned FeRAM has a very similar structure to that of DRAM, and uses a ferroelectric capacitor as a memory device. The ferroelectric substance has high residual polarization characteristics, such that data is not lost although an electric field is removed.

In this case, the RFID device uses frequencies of various bands. In general, as the value of a frequency band is decreased, the RFID device has a slower recognition speed, has a shorter operating distance, and is less affected by the surrounding environment (e.g., disruption from WiFi, cellphones, etc.). In contrast, as the value of a frequency band is increased, the RFID device has a faster recognition speed, has a greater operating distance, and is considerably affected by the surrounding environment. It may also be difficult to tell when a connection is made with a RFID tag or the status of the communication. This is especially true when there are several RFID tags in close proximity.

A plurality of RFID chips is included in a wafer in rows and columns. In order to perform dicing of each RFID chip at a wafer level, laser sawing may be used.

In addition, mask align keys, each of which is used as a reference for separating individual RFID chips from one another, are formed on a scribe lane (also called a scribe line or scribe region) of a wafer. In other words, the scribe lane is sawed on a wafer by a laser beam, such that individual RFID chips can be separated from one another. Therefore, a cutter for separating each chip is required for the sawing process, resulting in increased production time and costs.

Also, a conventional RFID device forms a mask align key on a scribe lane, such that an interval between chips is increased due to an area of a scribe lane. In other words, one scribe lane for separating each chip and the other scribe lane for arranging align keys are spaced apart at intervals of the same distance, and these scribe lanes are arranged among respective chips. As a result, the number of net dies on a wafer is decreased.

### BRIEF SUMMARY OF THE INVENTION

Various embodiments of the present invention are directed to providing a wafer and a method for forming the same that substantially obviate one or more problems due to limitations and disadvantages of the related art.

An embodiment of the present invention relates to a wafer technology for allowing each memory chip to be diced using a Deep Reactive Ion Etching (DRIE) process without performing an additional sawing process on a wafer including a plurality of memory chips.

An embodiment of the present invention relates to a wafer technology for allowing each RFID chip to be diced using a DRIE process without performing an additional sawing process on a wafer including a plurality of memory chips.

An embodiment of the present invention relates to a wafer technology for reducing an area of a scribe lane which is used to separate each chip from a wafer.

An embodiment of the present invention relates to a wafer technology for arranging an alignment key on a chip, such that a scribe-lane area can be reduced.

An embodiment of the present invention relates to a wafer technology for simultaneously performing a DRIE process on an overall wafer, such that fabrication time and costs requisite for dicing a wafer can be greatly reduced.

In accordance with one embodiment of the present invention, a wafer includes a plurality of chips configured to be arranged in row and column directions on the wafer, a scribe lane formed among the plurality of chips, configured to separate each of the plurality of chips using a Deep Reactive Ion Etching (DRIE) process, and an alignment key pattern configured to be arranged on the plurality of chips, wherein the DRIE process is performed at a front side of the wafer on a basis of the align key pattern.

In accordance with another embodiment of the present invention, a method for processing a wafer, the method comprising, providing the wafer, the wafer including a first chip area, a second chip area, and a scribe lane for separating the first chip area and the second chip area from each other includes forming a circuit area on a semiconductor substrate, forming a passivation layer on the circuit area; forming a trench area in an area of the scribe lane, exposing the trench area by performing a backgrinding process at a back side of the semiconductor substrate, and performing a wafer mounting process on the semiconductor substrate including the trench area.

The above-mentioned exemplary embodiments of the present invention have the following characteristics.

First, a wafer and a method for forming the same according to one aspect of the present invention can allow each memory chip to be diced using a DRIE process without performing an additional sawing process on a wafer including a plurality of memory chips, resulting in reduction in fabrication time and costs.

Second, a wafer and a method for forming the same according to another aspect of the present invention can allow each RFID chip to be diced using a DRIE process without performing an additional sawing process on a wafer including a plurality of memory chips, resulting in reduction in fabrication time and costs.

Third, a wafer and a method for forming the same according to another aspect of the present invention can reduce an area of a scribe lane which is used to separate each chip on a wafer, such that the number of net dies is increased.

Fourth, a wafer and a method for forming the same according to another aspect of the present invention can arrange an align key on a chip, such that a scribe-lane area can be reduced.

Fifth, a wafer and a method for forming the same according to another aspect of the present invention can simultaneously perform a DRIE process on an overall wafer, such that fabrication time and costs requisite for wafer dicing can be greatly reduced.

It is to be understood that both the foregoing general description and the following detailed description of the present invention are exemplary and explanatory and are intended to provide further explanation of the invention as claimed.

It will be appreciated by persons skilled in the art that that the effects that can be achieved with the present invention are not limited to what has been particularly described hereinabove and other advantages of the present invention will be more clearly understood from the following detailed description taken in conjunction with the accompanying drawings.

### BRIEF DESCRIPTION OF THE DRAWINGS

FIG. 1 is a block diagram illustrating a Radio Frequency Identification (RFID) chip according to an embodiment of the present invention.

FIGS. 2 to 3 illustrate a method for forming a wafer according to an embodiment of the present invention.

FIGS. 4 to 13 are cross-sectional views illustrating a method for forming a wafer according to an embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

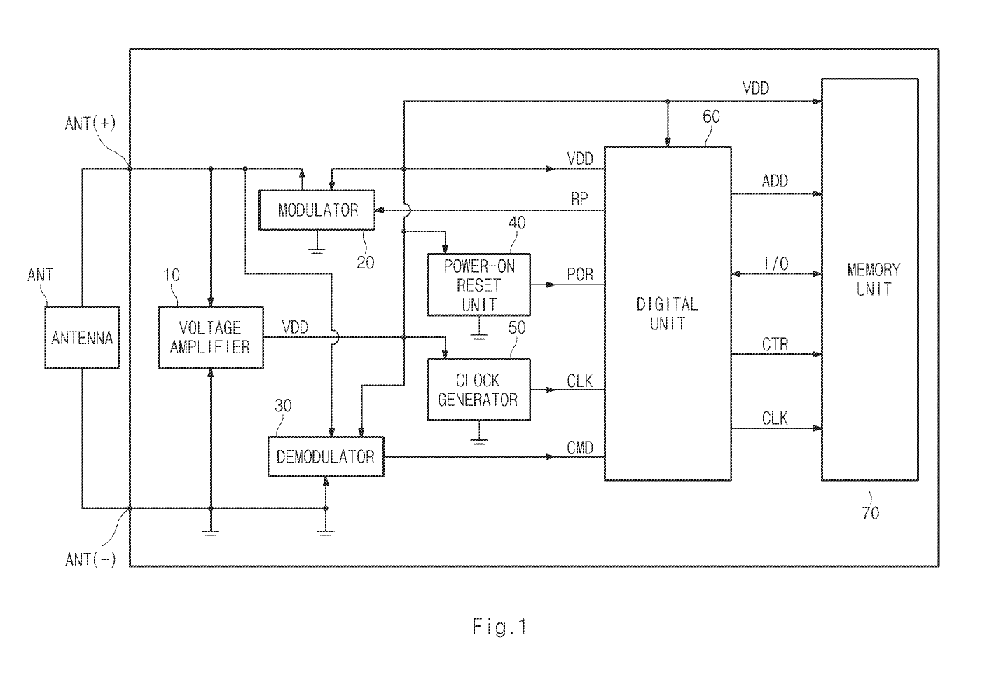

FIG. 1 is a block diagram illustrating a Radio Frequency Identification (RFID) chip according to an embodiment of the present invention.

Referring to FIG. 1, the RFID chip includes an antenna ANT, a voltage amplifier 10, a modulator 20, a demodulator 30, a power-on reset unit 40, a clock generator 50, a digital unit 60, and a memory unit 70.

In this case, the antenna ANT receives a radio frequency (RF) signal from an RFID reader. The RF signal received in the RFID device is input to the RFID chip via antenna pads ANT(+) and ANT(−).

The voltage amplifier 10 rectifies and boosts the RF signal received via the antenna ANT, and generates a power-supply voltage VDD serving as an RFID-device driving voltage.

The modulator 20 modulates a response signal RP received from the digital unit 60, and outputs the modulated response signal RP to the antenna ANT. The demodulator 30 demodulates the RF signal received from the antenna ANT in response to the output voltage of the voltage amplifier 10, and outputs a command signal CMD to the digital unit 60.

The power-on reset unit 40 detects a power-supply voltage generated in the voltage amplifier 10, and outputs a power-on reset signal POR to the digital unit 60 so as to control a reset operation in response to the detected power-supply voltage. In this case, detailed operations of the power-on reset signal POR are as follows. The power-on reset signal POR increases simultaneously with a power-supply voltage when the power-supply voltage changes from a low level to a high level. As soon as a power source reaches the power-supply voltage VDD, the power-on reset signal POR is changed from a high level to a low level, such that it is able to reset a circuit included in the RFID device.

The clock generator 50 outputs a clock signal CLK to the digital unit 60, wherein the clock signal CLK is capable of controlling operations of the digital unit 60 in response to the power-supply voltage VDD generated from the voltage amplifier 10.

The digital unit 60 receives a power-supply voltage VDD, a power-on reset signal POR, a clock signal CLK, and a command signal CMD, analyzes the command signal CMD, and generates a control signal and process signals. The digital unit 60 outputs a response signal RP corresponding to the control and process signals to the modulator 20. The digital unit 60 outputs an address ADD, input/output data I/O, a control signal CTR, and a clock signal CLK to the memory unit 70.

The memory unit 70 includes a plurality of memory cells. Each memory cell reads and writes data in a storage unit.

In this case, the memory unit 70 may be a non-volatile ferroelectric memory (FeRAM). The FeRAM has a data processing speed similar to that of a DRAM. Also, the FeRAM has a structure similar to that of DRAM, and uses a ferroelectric substance as a capacitor material so that it has high residual polarization characteristics. Due to the high residual polarization characteristics, data is not lost although an electric field is removed.

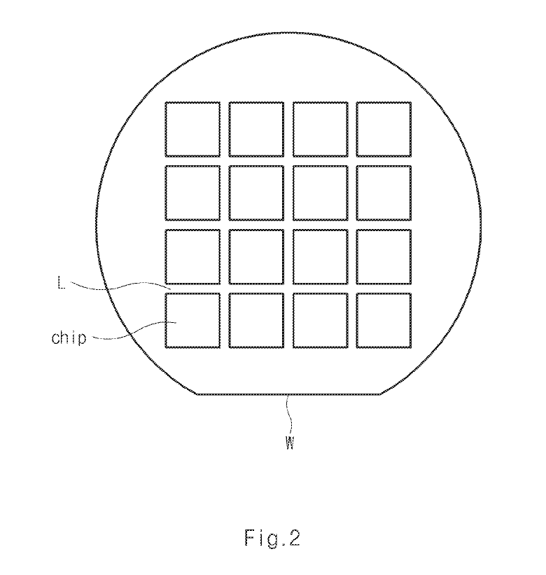

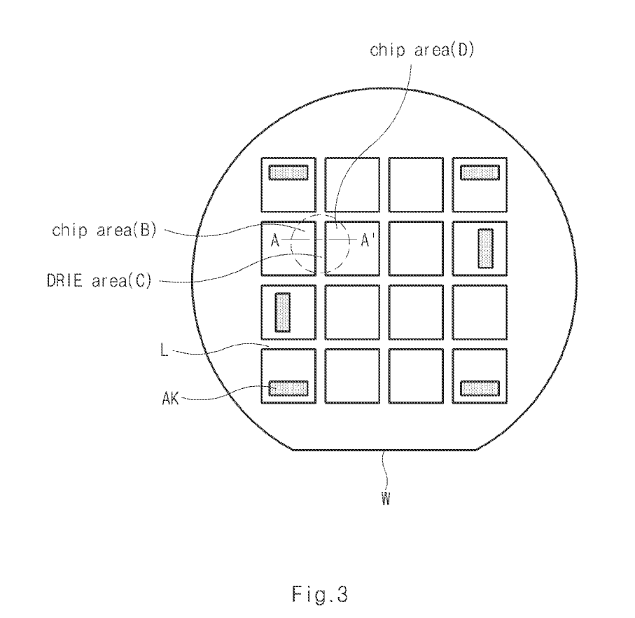

FIGS. 2 to 3 illustrate a method for forming a wafer according to an embodiment of the present invention. FIGS. 2 and 3 illustrate a cell array configuration and an alignment key configuration at a back side of a wafer according to an embodiment of the present invention.

Referring to FIGS. 2 and 3, a wafer according to an embodiment of the present invention may include an RFID chip, a DRAM, a FeRAM, or other memory chip, etc. For convenience of description and better understanding of the present invention, it is assumed that a wafer W to be described in the following embodiments is comprised of an RFID chip.

A plurality of RFID tag chip arrays are arranged on the wafer W in rows and columns. A scribe lane (or scribe region) L is arranged among individual RFID chips, such that it can separate and dice each chip by a Deep Reactive Ion Etching (DRIE) process.

In addition, an align key (or alignment key) AK may be arranged on a front side of each RFID chip of the wafer W. In this case, the align key AK may be used for a fabrication process onto a front side of the wafer W.

In accordance with the above-mentioned embodiment of the present invention, align key patterns are formed not in a scribe lane L, but in a chip area (B, D). Therefore, a scribe-lane area is reduced, and the number of net dies per wafer is increased.

That is, a technology according to the embodiment of the present invention performs a DRIE process starting from a front side of the wafer so as to dice each chip, such that a deep trench is formed.

The align key AK formed in a chip area may be arranged in a vertical and/or horizontal direction in the chip area.

In this case, no Complementary Metal-Oxide-Semiconductor (CMOS) circuit area is formed in an RFID chip including the align key AK, and no align key AK is formed in an RFID chip including the CMOS circuit area. In other words, the align key AK may be formed of a metal material. Therefore, in the RFID chip having no align key AK, each of metal lines M1˜Mn of the CMOS circuit area may serve as an align key.

Since the scribe lane L for separating chip areas will be patterned by a DRIE process using the align key AK as a reference in a subsequent step, the scribe lane L will be also referred to as a DRIE area C hereinafter. The DRIE area C may correspond to an area for forming a trench needed when a wafer is cut by the DRIE process at a front side of the wafer. An integrated circuit such as a RFID chip is formed over the front side of the substrate in the chip areas B and D.

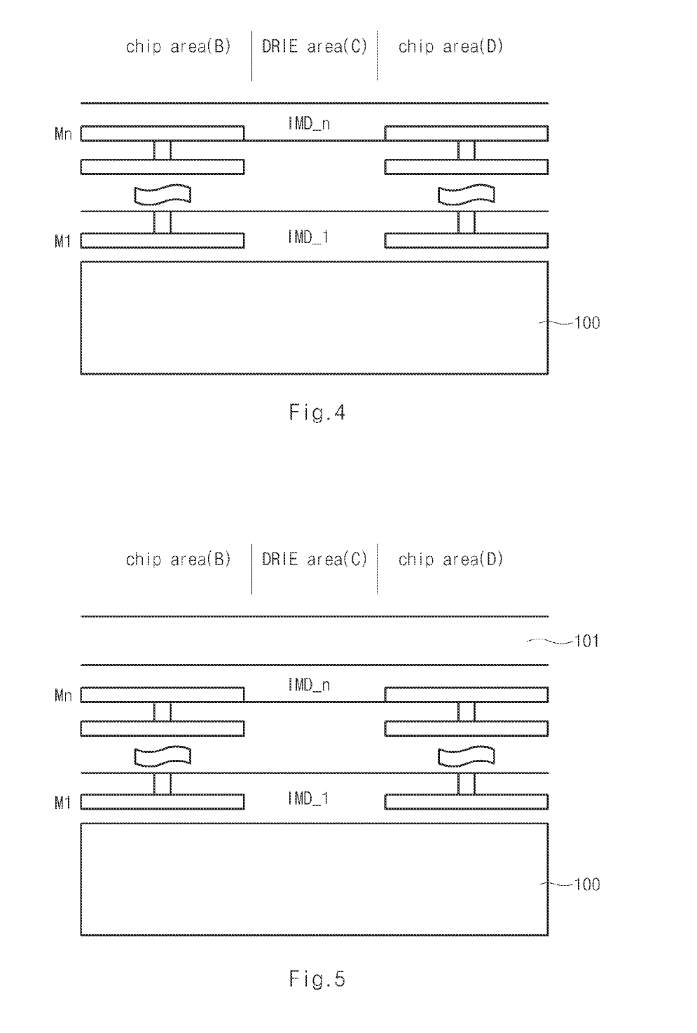

FIGS. 4 to 13 are cross-sectional views illustrating a method for forming a wafer according to an embodiment of the present invention. In more detail, FIGS. 4 to 13 are cross-sectional views illustrating wafers taken along the line A-A′ of FIG. 3. In accordance with the wafer structure of the embodiment of the present invention, a substrate is divided into a chip area B, a DRIE area C (i.e., scribe lane L), and an adjacent chip area D.

Subsequently, as shown in FIG. 4, a first integration structure, for example, a Complementary Metal-Oxide-Semiconductor (CMOS) circuit is formed over the semiconductor substrate 100 in the chip area (B, D) and a second integration structure is formed over the semiconductor substrate 100 in the DRIE area C. In this case, the first and the second integration structure are formed on a front side of the substrate in the chip areas B and D and the DRIE area C. The CMOS circuit area for implementing a CMOS element on a front side of the wafer may be formed in each of the chip area B and the other chip area D.

The semiconductor substrate 100 may be formed of silicon (Si), germanium (Ge), or germanium arsenide (GeAs), etc., but not limited thereto.

Several metal lines M1˜Mn and Inter Metal Dielectric (IMD) layers IMD_1˜IMD_n forming the first and the second integration structure are formed over the front side of the substrate 100. In this case, if the first integration structure includes a CMOS circuit, no separate align key pattern needs to be formed. Metal lines formed in a CMOS circuit may be used as an align key pattern during a subsequent making process defining the DRIE area C (or the scribe lane L) over the front side of the substrate 100. The CMOS circuit area may be used as an align key pattern for separating the chip area B and the other chip area D from each other.

Although the embodiment of FIG. 4 has disclosed that the CMOS circuit is formed only in each of the chip area B and the other chip area D as an example, the scope and spirit of the present invention are not limited thereto. For example, the metal lines M1˜Mn forming the CMOS circuit may be extended to the DRIE area C, or the DRIE area C may be formed of an oxide material.

Next, as shown in FIG. 5, a passivation layer 103 is formed over the substrate in the chip area B, the DRIE area C and the chip area D. Then, the front side of the wafer is turned face down for performing a series of back-side processes. When the substrate is turned over, a circuit structure formed over the front side of the substrate, e.g., the CMOS circuit, comes at the bottom, and thus the metal lines M1˜Mn on the top may be damaged. In order to protect the metal lines M1˜Mn, the passivation layer 101 is formed. The passivation layer 101 may be formed of a nitride material or a Polymide Isoindro Quirazorindione (PIQ) material.

The passivation layer 101 is formed for protecting the first circuit structures formed over the front side of the substrate 100.

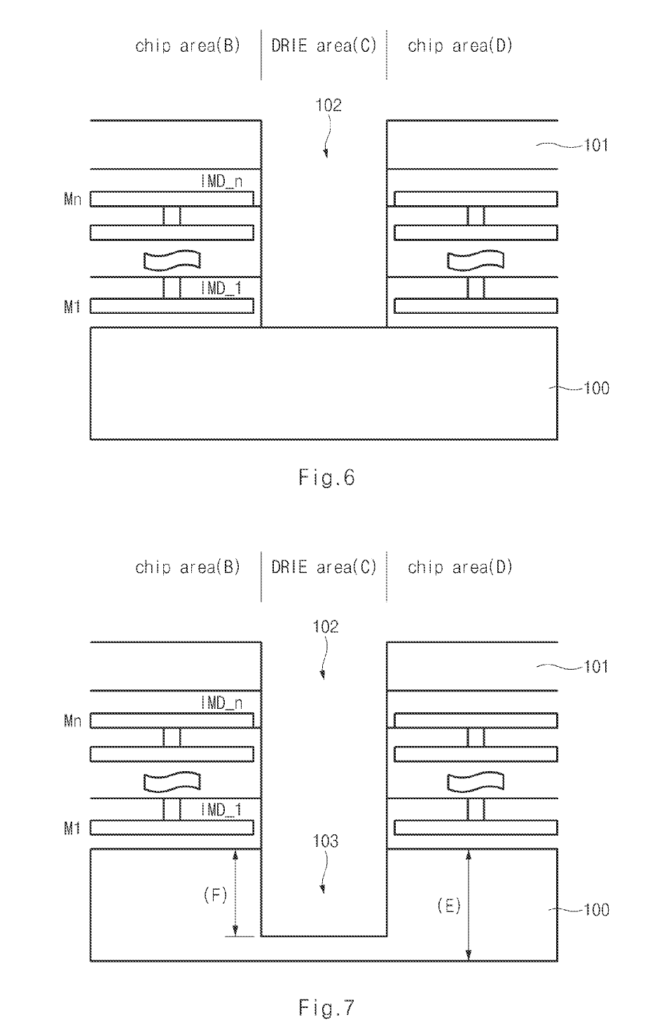

Subsequently, as shown in FIG. 6, the passivation layer 101 and the second integrated structure formed at the front side of the substrate in the DRIE area C are patterned away by a DRIE process. The passivation layer 101 and the CMOS circuit area (i.e., metal lines M1˜Mn and IMD layers IMD_1˜IMD_n) are etched at the front side of the wafer. In other words, the DRIE process is performed onto the front side of the substrate in the DRIE area C until the substrate is exposed to form a first trench 102.

In this case, only some parts of the passivation layer 101, the metal lines M1˜Mn, and the IMD layers IMD_1˜IMD_n which belong to the DRIE area C are etched such that the trench area 102 is formed. The first trench 102 is formed in the DRIE area C (scribe lane L) until the semiconductor substrate 100 is exposed.

Subsequently, as shown in FIG. 7, the semiconductor substrate 100 under the first trench 102 is patterned away. A DRIE process is formed onto the substrate exposed by the first trench 102 to form a second trench area 103 which is extended downward the first trench 102. The trench area 103 may be formed by etching the semiconductor substrate 100. That is, the DRIE process is formed on the front side of the wafer, such that the trench area 103 is formed on a silicon wafer for wafer dicing. The second trench area 103 is integrated with the trench 102 to form a third trench (102+103).

Assuming that the semiconductor substrate 100 has a thickness E of about 750 μm, it is preferable that a depth of the second trench 103 be set to about 500 μm˜750 μm. In this case, it should be noted that the thickness of the semiconductor substrate 100 is not limited only thereto, but is capable of being set to other values as necessary. As the wafer size is gradually increased, the semiconductor substrate 100 becomes thicker. For example, the thickness of the semiconductor substrate 100 may be set to about 600 μm, 550 μm, and the like.

The second trench 103 is deeply formed in the semiconductor substrate 100. The etched depth of the second trench area 103 is denoted by ‘F’. The range of the second trench 103 may be extended to penetrate the semiconductor substrate 100.

The scribe lane L may be formed of the third trench (102+103). In this case, the third trench (102+103) serves for separating chip areas from one another. The third trench (102+103) may correspond to the scribe lane L for separating each chip from others.

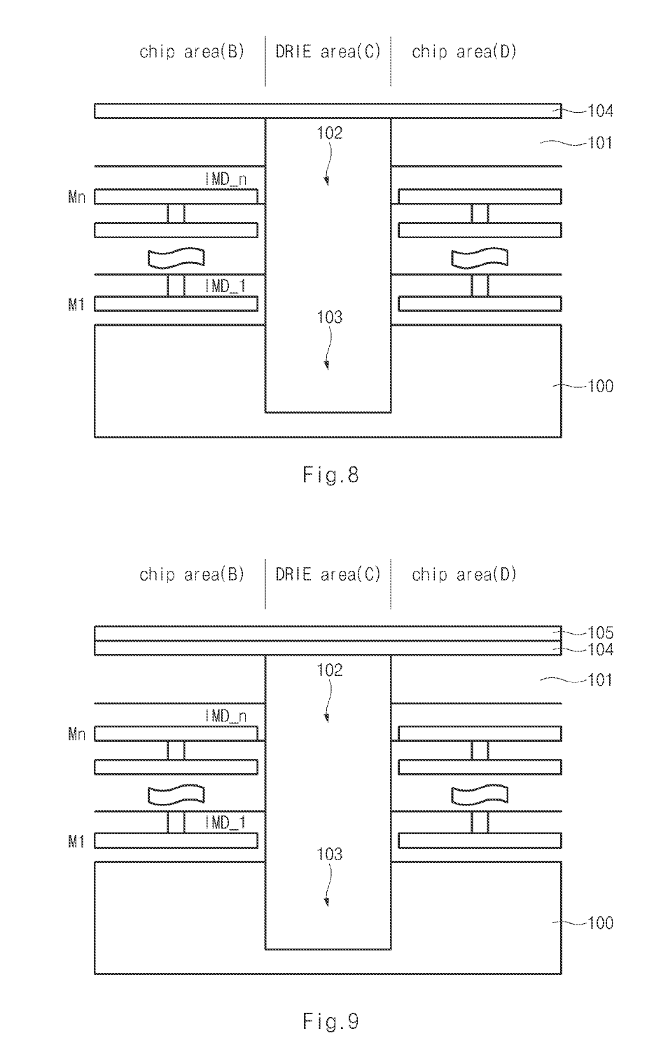

Subsequently, as shown in FIG. 8, a coating film 104 is deposited on the passivation layer 103 including the third trench (102+103). The coating film 104 may be formed to protect the circuit structures formed on the front side of the wafer. In this case, the coating film 104 is formed covering the third trench (102+103).

Thereafter, as shown in FIG. 9, a reinforcing film 105 is deposited on the coating film 104. In this case, the reinforcing film 105 serves as a physical support for protecting the wafer from an external physical stress. As a result, although the wafer receives stress from the outside, the reinforcing film 105 prevents the wafer from being distorted.

In more detail, in order to prevent the substrate 100 from being distorted during a back-grinding process performed on the back side of the substrate 100, the reinforcing film 105 is additionally formed on the coating film 104.

The reinforcing film 105 may be formed of a heat-resistant polymer layer, an aluminum foil tape, or the like.

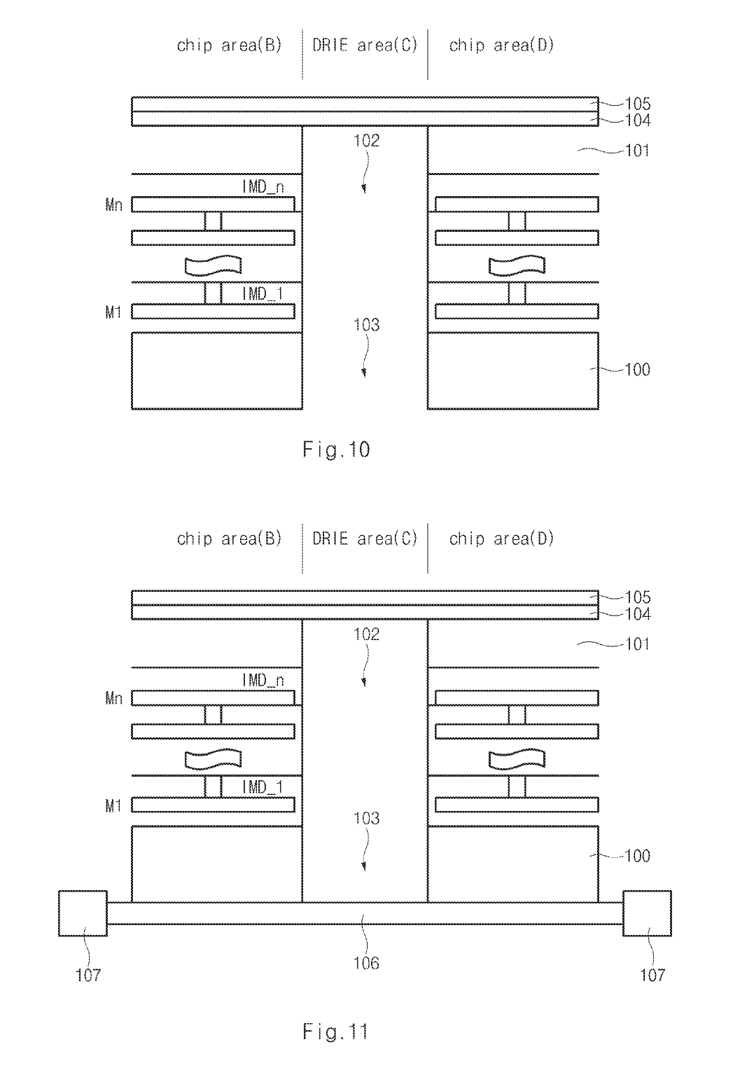

Next, referring to FIG. 10, the wafer is turned over to perform the back-grinding process onto the back side of the semiconductor substrate 100. In the case when the third trench (102+103) is not penetrating the substrate 100, the back-grinding process is performed until the third trench (102+103) is exposed.

For example, the second trench 103 can be formed in the semiconductor substrate 100 with a depth F of 200 μm˜300 μm, and the remaining semiconductor substrate 100 under the second trench 103 in the DRIE area C may have a thickness of about 150 μm. However, the thickness of the remaining semiconductor substrate 100 under the second trench 103 in the DRIE area C is not limited thereto.

It is preferable that the semiconductor substrate 100 be ground until the third trench (102+103) is exposed on the back side of the substrate 100.

Subsequently, as shown in FIG. 11, a ring film 106 is formed on the back side of the semiconductor substrate 100. A ring mount 107 is formed around the ring film 106.

The ring film 106 is used as a protection film, such that it protects the circuit structures such as RFID chips formed over the substrate while the wafer is delivered, or keeps the third trench (102+103) from distortion during a subsequent packaging process. For this purpose, the ring film 106 is detachably formed over the back side of the semiconductor substrate 100, such that the ring film 106 can be easily separated from the semiconductor substrate 100.

A method for forming the ring film 106, and the ring mount 107 will hereinafter be described in detail.

A wafer ring frame is formed on the semiconductor substrate 100 at a back side of a wafer. The wafer ring frame includes the ring film 105 and the donut-ring-shaped ring mount 107.

That is, the ring mount 107 for supporting the ring film 106 is formed around the ring film 106. The ring film 106 is formed over the back side of the substrate 100. In this case, the back side of the semiconductor substrate 100 may be in contact with the ring film 106.

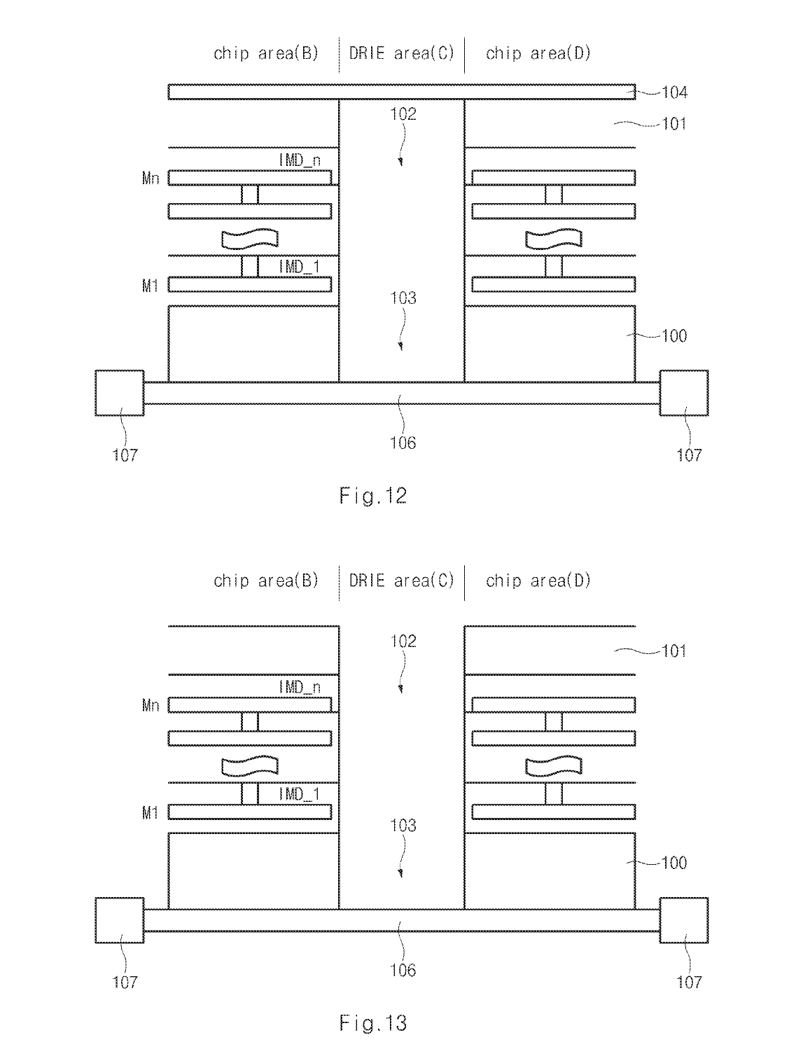

Thereafter, as shown in FIG. 12, the wafer is turned over again so that the front side of the substrate faces up. Then, the reinforcing film 105 is removed. Then, as shown in FIG. 13, the coating film 104 formed on the passivation layer 101 and the third trench (102+103) is removed. Therefore, a semiconductor device according to the embodiment of the present invention which includes diced chip areas is obtained. The dicing process of the wafer chip is performed by a DRIE process, rather than a conventional wafer sawing process.

Since a dicing process is performed onto the scribe lane L to separate the chip areas B and D by a DRIE process and not by a conventional sawing process, the area of the scribe lane L can significantly reduced.

As apparent from the above description, the above-mentioned embodiments of the present invention have the following characteristics.

First, a wafer and a method for forming the same according to one aspect of the present invention can allow each memory chip to be diced using a DRIE process without performing an additional sawing process on a wafer including a plurality of memory chips, resulting in a reduction in fabrication time and costs.

Second, a wafer and a method for forming the same according to another aspect of the present invention can allow each RFID chip to be diced using a DRIE process without performing an additional sawing process on a wafer including a plurality of memory chips, resulting in a reduction in fabrication time and costs.

Third, a wafer and a method for forming the same according to another aspect of the present invention can reduce an area of a scribe lane which is used to separate each chip on a wafer, such that the number of net dies is increased.

Fourth, a wafer and a method for forming the same according to another aspect of the present invention can arrange an align key on a chip, such that a scribe-lane area can be reduced.

Fifth, a wafer and a method for forming the same according to another aspect of the present invention can simultaneously perform a DRIE process on an overall wafer, such that fabrication time and costs requisite for wafer dicing can be greatly reduced.

Although a number of illustrative embodiments consistent with the invention have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. A wafer comprising:
a plurality of chips configured to be arranged in row and column directions on the wafer;
a scribe lane formed among the plurality of chips, configured to separate each of the plurality of chips using a Deep Reactive Ion Etching (DRIE) process; and
an align key pattern configured to be arranged on the plurality of chips,
wherein the DRIE process is performed at a front side of the wafer on a basis of the align key pattern.

2. The wafer according to claim 1, wherein each of the chips includes a radio frequency identification (RFID) chip.

3. The wafer according to claim 2, wherein the RFID chip includes a non-volatile ferroelectric memory.

4. The wafer according to claim 1, wherein the align key pattern is distributively arranged in a vertical or horizontal direction of a predetermined area of the plurality of chips.

5. The wafer according to claim 1, wherein the align key pattern includes a Complementary Metal-Oxide-Semiconductor (CMOS) circuit area formed on the plurality of chips at a front side of the wafer.

6. A method for processing a wafer, the method comprising:
Providing the wafer, the wafer including a first chip area, a second chip area, and a scribe lane for separating the first chip area and the second chip area from each other;
forming a circuit area over a semiconductor substrate;
forming a passivation layer over the circuit area;
forming a trench area in an area of the scribe lane;
exposing the trench area by performing a backgrinding process at a back side of the semiconductor substrate; and
performing a wafer mounting process on the semiconductor substrate including the trench area.

7. The method according to claim 6, wherein the circuit area includes an align key.

8. The method according to claim 6, wherein the circuit area is formed in each of the first chip area and the second chip area.

9. The method according to claim 6, wherein the circuit area includes a metal line extended to the scribe line, and an Inter Metal Dielectric (IMD) layer.

10. The method according to claim 6, wherein the passivation layer is formed on each of the first chip area, the second chip area, and the scribe line.

11. The method according to claim 6, wherein the forming of the trench area includes:
forming a first trench by etching the passivation layer and the circuit area formed in the scribe lane area; and
forming a second trench by etching the semiconductor substrate formed in the scribe lane area.
a second trench on the semiconductor substrate; and
burying a filling material in the second trench.

12. The method according to claim 11, wherein the first trench is etched until an upper part of the semiconductor substrate is exposed.

13. The method according to claim 6, wherein the first trench is formed at a front side of the semiconductor substrate by a Deep Reactive Ion Etching (DRIE) process.

14. The method according to claim 6, further comprising:
after forming the trench area,
forming a coating film over the passivation layer; and
forming a reinforcing film over the coating film.

15. The method according to claim 14, wherein the reinforcing film includes a polymer layer.

16. The method according to claim 14, wherein the reinforcing film includes an aluminum foil tape.

17. The method according to claim 6, wherein the mounting process includes:
forming a ring film to which the semiconductor substrate including the trench area is mounted; and
forming a ring mount along an outline of the ring film.

18. The method according to claim 6, further comprising:
after performing the mounting process, removing a reinforcing film formed on the passivation layer.

19. The method according to claim 6, further comprising:
after performing the mounting process, removing a coating film formed over the passivation layer.

20. The method according to claim 6, wherein each of the first chip area and the second chip area includes a radio frequency identification (RFID) chip.
